(19) United States
(12) Patent Application Publication
(10) Pub. No.: US 2010/0198537 A1
(43) Pub. Date: Aug. 5, 2010

(54) ELECTRONIC DEVICE AND METHOD FOR CALCULATING REMAINING USABLE TIME OF BATTERY

(75) Inventor: Yoshiharu Takemori, Osaka (JP)

Correspondence Address: HAMRE, SCHUMANN, MUELLER & LARSON P.C., P.O. BOX 2902, MINNEAPOLIS, MN, 55402-0902, US

(73) Assignee: PANASONIC CORPORATION, Osaka (JP)

(21) Appl. No.: 12/647,180

(22) Filed: Dec. 24, 2009

(30) Foreign Application Priority Data
Dec. 26, 2008 (JP) 2008-332548

(51) Int. Cl. G01R 31/36

(52) U.S. Cl. 702/63

(57) ABSTRACT

A video camera 101 includes a liquid crystal monitor 102 and charging microcomputer 103. The charging microcomputer 103 includes a battery remaining capacity detector 13a, a timer 13b, and a usable time calculating section 13c. The usable time calculating section 13c is configured to: (i) calculate a remaining usable time based on a value regarding a remaining capacity of a battery 201 detected by the battery remaining capacity detector 13a and a value regarding a current consumption of the video camera 101, during a period from when the video camera 101 starts operating using the battery 201 until the remaining usable time of the battery reaches a predetermined threshold time, and (ii) calculate the remaining usable time based on an operating time measured by the timer, during a period from after the remaining usable time becomes less than the threshold time until the remaining usable time becomes zero.

### BACKGROUND OF THE INVENTION

1. Field of the Invention

The present invention relates to an electronic device driven by a battery. Particularly, the present invention relates to an electronic device capable of displaying a remaining usable time of a battery. The present invention also relates to a method for calculating a remaining usable time of a battery.

2. Description of Related Art

Some of electronic devices driven by a battery have a function of displaying a remaining usable time as a remaining capacity of the battery. For example, WO 2008/069046 discloses an electronic device capable of displaying a remaining capacity of a battery. The battery is provided with a battery microcomputer that can output battery information including the remaining capacity information. This electronic device includes a main microcomputer for acquiring the battery information from the battery microcomputer and calculating an actual value of the remaining capacity as the actual remaining capacity of the battery based on the battery information, and a display unit for displaying the remaining capacity of the battery by the controlling from the main microcomputer. The main microcomputer calculates a corrected value of the remaining capacity by subtracting a correction margin value specific to the battery from the actual value of the remaining capacity, and controls the display unit to display zero as the remaining capacity of the battery when the corrected value of the remaining capacity is equal to or less than the correction margin value.

### SUMMARY OF THE INVENTION

However, even the above-mentioned electronic device fails to display accurately the remaining usable time in some cases. Particularly, the display of the remaining usable time tends to be inaccurate during a period immediately before battery exhaustion.

An object of the present invention is to provide a technique for displaying accurately the remaining usable time of a battery, particularly, the remaining usable time of a battery during a period immediately before battery exhaustion.

More specifically, the present invention provides an electronic device including:

a battery remaining capacity detector configured to detect a remaining capacity of a battery;

a timer configured to measure an operating time of the electronic device;

a usable time calculating section configured to: (i) calculate a remaining usable time based on a value regarding the remaining capacity of the battery detected by the battery remaining capacity detector and a value regarding a current consumption of the electronic device, during a period from when the electronic device starts operating using the battery until the remaining usable time of the battery reaches a predetermined threshold time, and (ii) calculate the remaining usable time based on the operating time measured by the timer, during a period from after the remaining usable time becomes less than the threshold time until the remaining usable time becomes zero; and

a display unit configured to display information regarding the remaining usable time calculated by the usable time calculating section.

In another aspect, the present invention provides a method for calculating a remaining usable time of a battery, including the steps of:

detecting a remaining capacity of the battery;

measuring an operating time of an electronic device connected to the battery;

calculating the remaining usable time based on a value regarding the detected remaining capacity of the battery and a value regarding a current consumption of the electronic device, during a period from when the electronic device starts operating using power of the battery until the remaining usable time of the battery reaches a predetermined threshold time;

calculating the remaining usable time based on the operating time measured by the timer, during a period from after the remaining usable time becomes less than the threshold time until the remaining usable time becomes zero; and

displaying information regarding the calculated remaining usable time.

In the present invention, the remaining usable time can be calculated accurately in accordance with the remaining capacity of the battery during the period until the remaining usable time of the battery reaches the predetermined threshold time. After the remaining usable time becomes less than the threshold time, the remaining usable time can be reduced so as to be consistent with an actual lapsed time.

### BRIEF DESCRIPTION OF DRAWINGS

FIG. 1 is a block diagram showing configurations of an electronic device and a battery according to an embodiment of the present invention.

FIG. 2A is a graph showing an ideal relationship between a displayed remaining usable time and an actual lapsed time.

FIG. 2B is a graph showing a deviation between the displayed remaining usable time and the actual lapsed time.

FIG. 3A is a graph showing a variation in current consumption over time.

FIG. 3B is a graph showing a relationship between the variation in current consumption over time and a predetermined correction value.

FIG. 4 is a graph showing a variation in a remaining capacity of the battery over time.

FIG. 5 is a flow chart showing a process for calculating the remaining usable time of the battery.

FIG. 6 is a graph showing a variation in the remaining usable time displayed on a liquid crystal monitor.

FIG. 7 is a block diagram showing a configuration of an electronic device according to a modified example.

### DETAILED DESCRIPTION OF THE INVENTION

Hereinafter, a description will be made with regard to an embodiment in which an electronic device of the present invention is applied to a video camera, with reference to the accompanying drawings.

(1. Configuration of the Electronic Device)

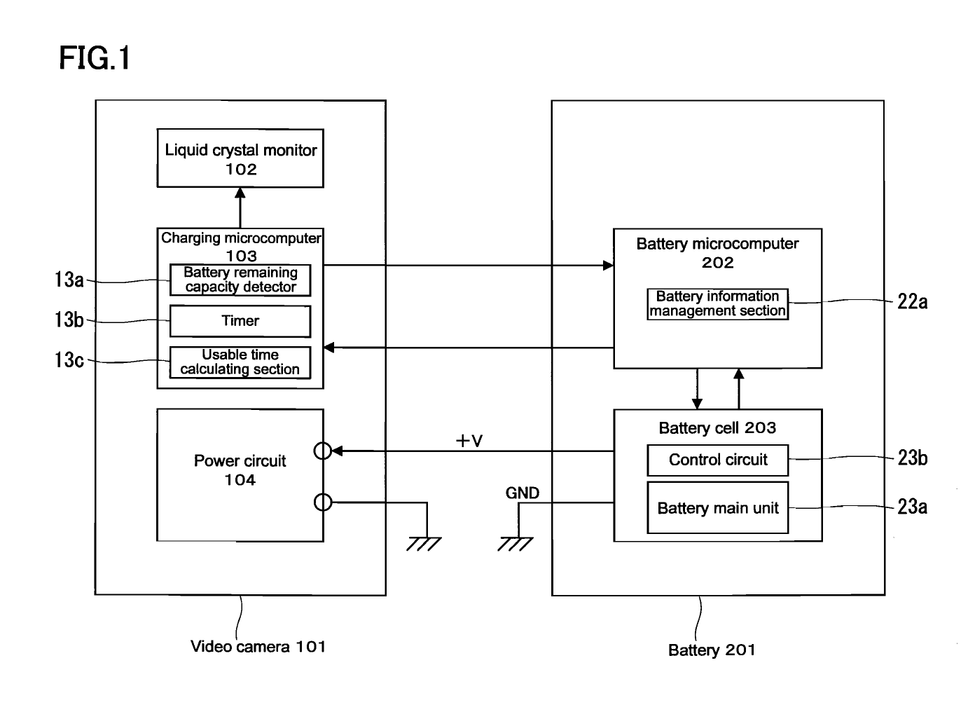

FIG. 1 is a block diagram showing configurations of the electronic device and a battery according to the present embodiment. A video camera 101 includes a liquid crystal monitor 102, a charging microcomputer 103, and a power circuit 104. The video camera 101 also includes an optical system, an image pickup element, an image processing section, a recording medium control section, etc., none of which are shown in FIG. 1. A battery 201 is a battery unit including a battery microcomputer 202 and a battery cell 203, and is removable from the video camera 101.

The liquid crystal monitor 102 displays an image being picked up as well as a remaining usable time of the battery 201. The remaining usable time means a remaining time during which the mounted battery 201 can continue driving the video camera 101. The remaining usable time is displayed in minute units, for example. Instead of the liquid crystal monitor 102 or together with the liquid crystal monitor 102, another display unit, such as an electronic view finder, may be provided. Moreover, the remaining usable time does not necessarily have to be displayed in characters. For example, it can be displayed using at least one information selected from the group consisting of a character, a graphic, and a symbol.

The charging microcomputer 103 includes a battery remaining capacity detector 13a, a timer 13b, and a usable time calculating section 13c. The charging microcomputer 103 makes serial communication with the battery 201 (specifically, with the battery microcomputer 202) via a battery connecting portion (not shown) so as to acquire various information regarding the battery 201. The various information regarding the battery 201 include a remaining capacity of the battery 201. More specifically, the battery remaining capacity detector 13a detects the remaining capacity of the battery 201. The usable time calculating section 13c calculates the remaining usable time of the battery 201 by using the various information acquired. The timer 13b measures various times, such as a time during which the video camera 101 has been used (an operating time of the video camera 101).

The power circuit 104 supplies power from the battery 201 to each part of the video camera 101.

The battery cell 203 is composed of a battery main unit 23a and a control circuit 23b such as a protection circuit. The battery main unit 23a is composed of a lithium ion secondary battery, for example. The battery microcomputer 202 includes a battery information management section 22a. The battery information management section 22a serves to manage the information regarding the battery 201, such as the type of the battery 201 and the remaining capacity of the battery 201. Specifically, the battery information management section 22a calculates successively the remaining capacity (mAh) of the battery 201 and stores it, using an integrated value of the current (mA) supplied from the battery main unit 23a to the power circuit 104 and an integrated value of the current supplied to the battery main unit 23a when the battery 201 is charged. By querying the battery information management section 22a, it is possible to know the remaining capacity of the battery 201 at the time of the querying. Also, it is possible to know the amount of the current being supplied from the battery 201 to the video camera 101 at the time of the querying.

Typically, the functions that the charging microcomputer 103 and the battery microcomputer 202 should provide can be realized by a combination of hardware and software. It should be noted, however, that a part of or all of each of the charging microcomputer 103 and the battery microcomputer 202 may be composed of hardware only.

(2. Method for Calculating the Remaining Usable Time)

### (2-1. Problem in Calculating the Remaining Usable Time Based on the Remaining Capacity of the Battery and Current Consumption)

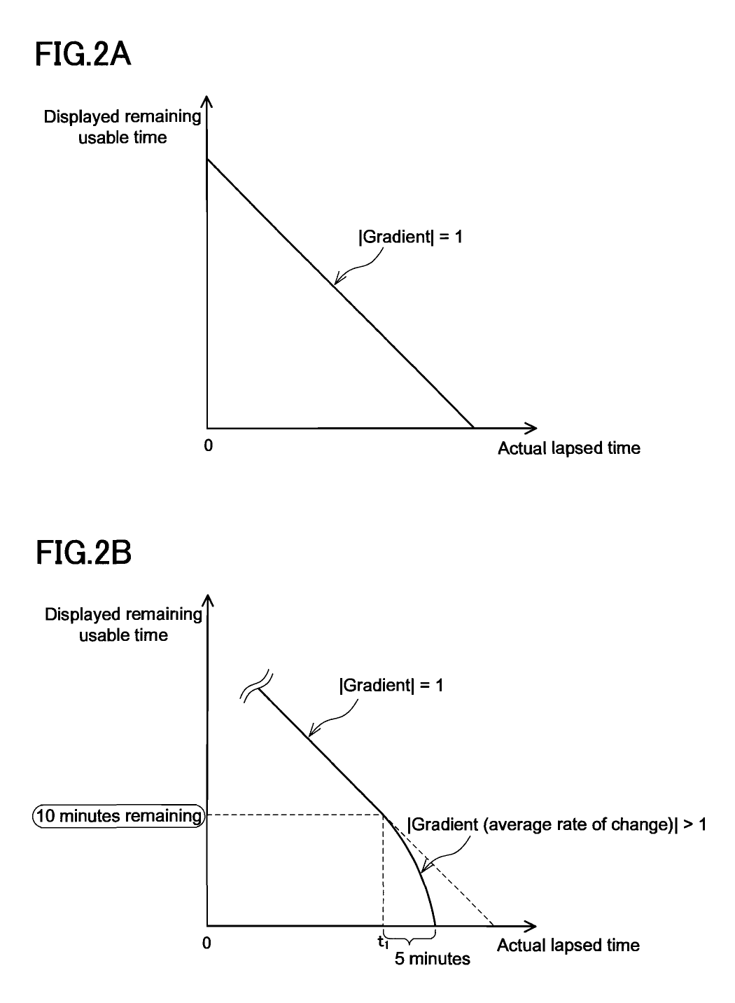

FIG. 2A is a graph showing an ideal relationship between a displayed remaining usable time and an actual lapsed time. As shown in FIG. 2A, it is ideal that a rate of change (gradient) in the displayed remaining usable time be consistent with the actual lapsed time.

The remaining usable time of the battery 201 can be calculated using the remaining capacity E (mAh) of the battery 201 and current consumption I (mA) of the video camera 101. The remaining capacity E (mAh) of the battery 201 is calculated successively and managed by the battery information management section 22a. Generally, the remaining usable time is equal to E/I. The current consumption I denotes a current being supplied from the battery 201 to the video camera 101.

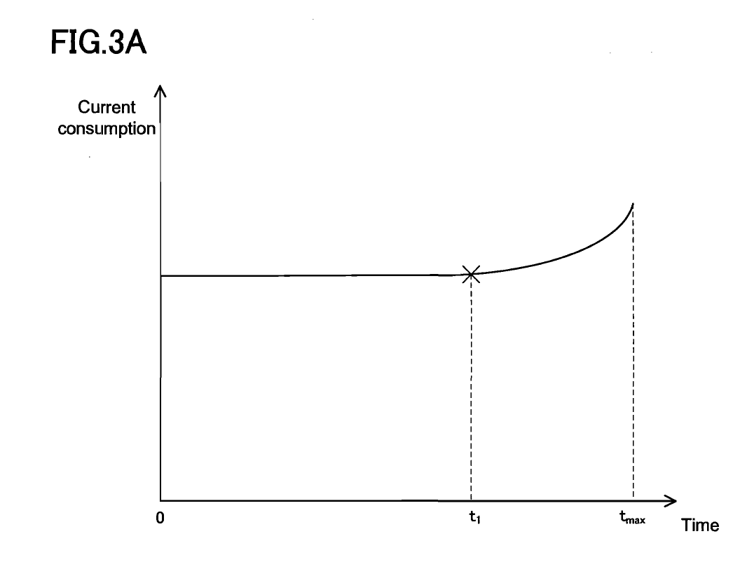

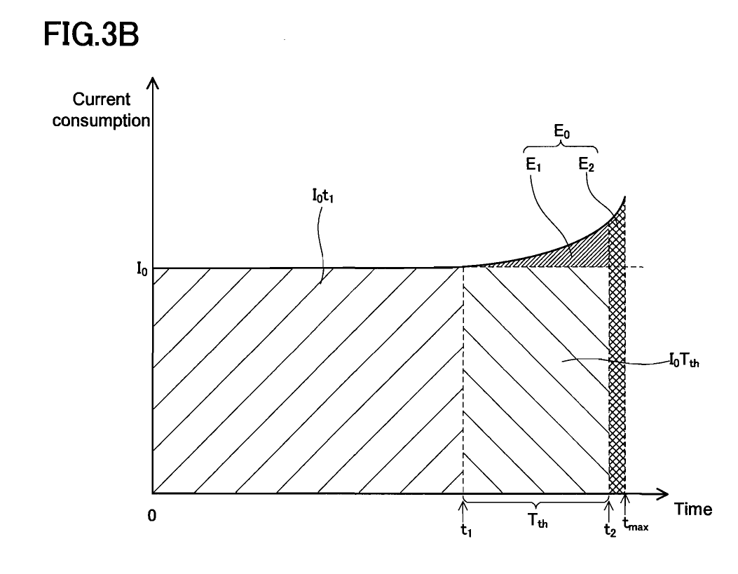

Here, when the range of variation in the current consumption I is narrow, the remaining usable time exhibits a satisfactory linearity with respect to the actual lapsed time. However, when the range of variation in the current consumption I is wide, the linearity is lost. For example, assume that an approximately constant current is supplied during a period from the start of using the video camera 101 to time t₁, but the current varies significantly over time during a period from the time t₁ to time tₘₐₓ at which the battery is exhausted, as shown in FIG. 3A. During the period from the start of using the video camera 101 to the time t₁, the remaining usable time, which is calculated by E/I, exhibits a satisfactory linearity with respect to the actual lapsed time. During the period from the time t₁ to the time tₘₐₓ at which the battery is exhausted, the remaining usable time, which is calculated by E/I, exhibits a poor linearity with respect to the actual lapsed time.

Thus, if the remaining usable time continues to be calculated by E/I, a problem occurs in a period immediately before the battery exhaustion. Specifically, as shown in FIG. 2B, there occurs a case where an indication saying “10 minutes remaining” is displayed at the time t₁ but the battery actually will be exhausted 5 minutes after the time t₁. A minor error makes no significant problem when the remaining usable time is sufficient. However, an error generated during the period immediately before the battery exhaustion possibly causes an unexpected disadvantage to a user. Taking a video camera, for example, there possibly occurs a problem such that the battery is exhausted sooner than expected and the user misses a chance to take the scene that he/she wants to record.

A lithium ion secondary battery is known as a battery in which the current consumption I varies in a wide range during the period immediately before the battery exhaustion. In the lithium ion secondary battery, the voltage begins to decrease suddenly when the remaining capacity of the lithium ion secondary battery becomes less than a certain capacity. Since the power consumption of an electronic device, such as a video camera, almost is constant, a larger amount of current is taken from the lithium ion secondary battery during the period immediately before the battery exhaustion. That is, the remaining capacity decreases rapidly during the period immediately before the battery exhaustion.

(2-2. Calculation of the Remaining Usable Time According to the Present Embodiment)

Facing the above-mentioned problem, the present embodiment proposes the following method. In this method, attention is focused on the fact that a true remaining usable time of the battery 201 after the time t₁ can be measured experimentally in advance. Describing with reference to FIG. 2B, the true remaining usable time of the battery 201 after the time t₁ is 5 minutes, which can be measured experimentally in advance. Thus, the remaining usable time is calculated by E/I during a period from when the video camera 101 starts operating using the battery 201 until the time t₁. After the time t₁, the actual lapsed time is subtracted successively from the true remaining usable time measured experimentally in advance. Thereby, the speed at which the remaining usable time decreases can be consistent with the actual lapsed time even after the time t₁.

However, the following problem still remains. First, suppose that the calculation result of E/I is “5 minutes.” The remaining usable time of “5 minutes” calculated by E/I means that “the battery can be used for another 5 minutes if the present current consumption I still continues hereafter”, and does not necessarily indicate the true remaining usable time. Describing with reference to FIG. 2B, the point of “10 minutes remaining” calculated by E/I actually is the true time t₁ of “5 minutes remaining.” Thus, at the moment at which the method for calculating the remaining usable time is switched from the method using E/I to the method using the actual lapsed time, it is necessary to switch suddenly the indication saying “10 minutes remaining” to the indication saying “5 minutes remaining.” As mentioned above, an error generated during the period immediately before the battery exhaustion possibly causes an unexpected disadvantage to a user.

Hence, in order to correct the error between the “10 minutes remaining” calculated by E/I and the true “5 minutes remaining”, a time equivalent to the error is subtracted in advance from the remaining usable time determined by E/I.

For example, even when the result calculated by E/I is 10 minutes, the liquid crystal monitor 102 displays the indication “5 minutes remaining”. Thereby, the error between the remaining usable time calculated by E/I and the true remaining usable time can be eliminated.

The error may be eliminated by any method. That is, there is no problem as long as a time less than the remaining usable time calculated by E/I is calculated as the remaining usable time to be displayed on the liquid crystal monitor 102. In the present embodiment, the remaining usable time to be displayed on the liquid crystal monitor 102 is calculated by dividing a value found by subtracting E₀ from E by the current consumption I, where E denotes the remaining capacity of the battery 201 and E₀ denotes a predetermined correction value. That is, the remaining usable time is calculated using the remaining capacity (E−E₀) less than the actual remaining capacity E managed by the battery microcomputer 202.

The predetermined correction value E₀ can be calculated by the following method. As described above, the true remaining usable time of the battery 201 after the time tᵢ can be measured experimentally in advance. Describing with reference to FIG. 3B, the battery 201 can be used up to the time tₘₐₓ at most. The “time t₁” and “time tₘₐₓ” each are a variable, but (tₘₐₓ−t₁) is a value specific to the battery 201. (tₘₐₓ−t₁) is equivalent to the true remaining usable time of the battery 201 after the time t₁. However, taking into account that the remaining capacity E managed by the battery microcomputer 202 also includes some error, a time less than (tₘₐₓ−t₁) is defined as “threshold time Tₜₕ”. The battery 201 can be used until time t₂, which is a point when the threshold time Tₜₕ has passed since the time t₁. The threshold time Tₜₕ is the remaining usable time of the battery 201 after the time t₁, and is set appropriately in accordance with the capacity of the battery 201, etc. For example, the threshold time Tₜₕ can be set so that (tₘₐₓ−t₁−Tₜₕ) falls within the range of 1 to 10 minutes. In the example shown in FIG. 2B, the threshold time Tₜₕ is 5 minutes.

The power supplied from the battery 201 to the video camera 101 is indicated with an integrated value of the current consumption I. For example, when the battery main unit 23a is composed of the lithium ion secondary battery, the video camera 101 exhibits an approximately flat current consumption property during the period from the start of using the video camera 101 to the time t₁. The current consumption in this flat region is referred to as I₀. The power consumption during the period from the start of using the video camera 101 to the time t₁ is denoted as I₀t₁. The power consumption during the period from the time t₁ to the time t₂ is referred to as I₀Tₜₕ+E₁. I₀Tₜₕ denotes a power to be consumed when the current consumption is assumed to be constant (at I₀) until the remaining usable time becomes zero. In reality, the power denoted as “E₁” additionally is consumed because the current consumption continues increasing during the period from the time t₁ to the time t₂.

Moreover, as mentioned above, a time less than (tₘₐₓ−t₁) is set as the “threshold time Tₜₕ.” Thus, at the time t₂, the power denoted as “E₂” remains in the battery 201 theoretically. Eventually, the correction value E₀ can be represented by “E₁+E₂”. When the remaining capacity of the battery 201 at a point of time when the remaining usable time reaches the threshold time Tₜₕ, that is, at the time t₁, is defined as E(t₁), the correction value E₀ can be represented by formula (1) below.

E(t₁)=E₀+I₀Tₜₕ (1)

In the present embodiment, average current consumption I₀ of the video camera 101 is used for calculating the remaining usable time. The average current consumption I₀ can be found experimentally by the following method. First, the battery 201 is mounted on the video camera 101 and the current consumption of the video camera 101 is measured in time series. Then, the measured current consumption is averaged. Thus, the average current consumption I₀ is found. Alternatively, the average current consumption I₀ theoretically can be found from the properties of the battery 201 (typically, the properties of the lithium ion secondary battery), assuming that the power consumption of the video camera 101 is constant.

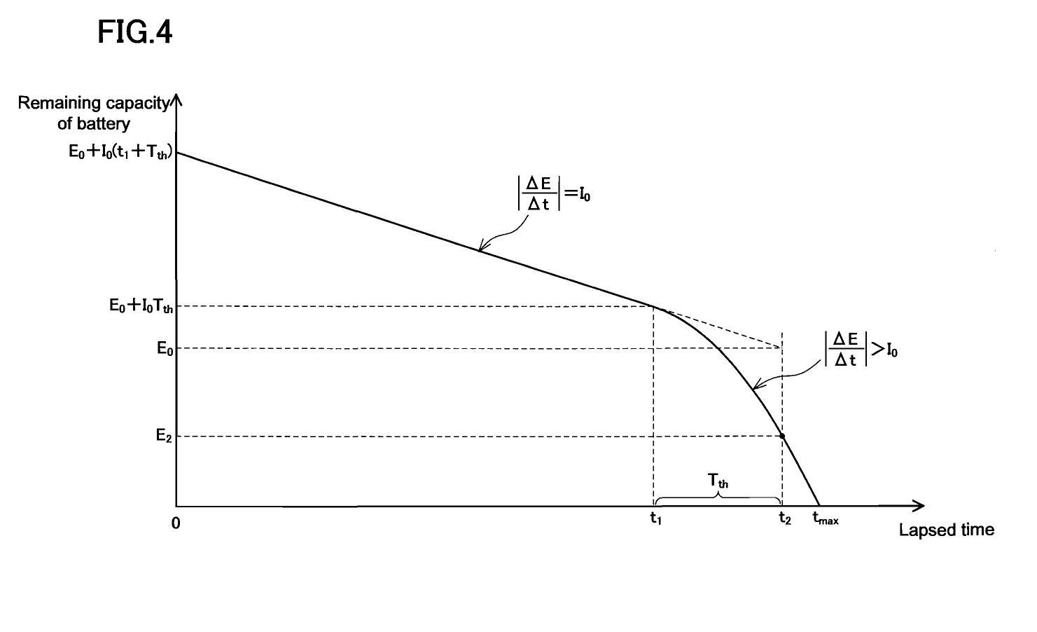

FIG. 4 is a graph showing a variation in the remaining capacity of the battery over time. As is apparent from FIG. 3B, the remaining capacity E of the battery 201 is equal to E₀+I₀ (t₁+Tₜₕ) at the start of using the video camera 101. The remaining capacity E decreases at an approximately constant rate until the operating time reaches the time t₁. Specifically, (ΔE/Δt)=I₀ holds, where ΔE denotes an amount of variation in the remaining capacity E during an extremely short time Δt. At the time t₁, the remaining capacity E is equal to E₀+I₀Tₜₕ. (ΔE/Δt)>I₀ holds during the period from the time t₁ to the time t₂. At the time t₂, the remaining capacity E is equal to E₂.

(3. Flow Chart Showing a Process for Calculating the Remaining Usable Time of the Battery)

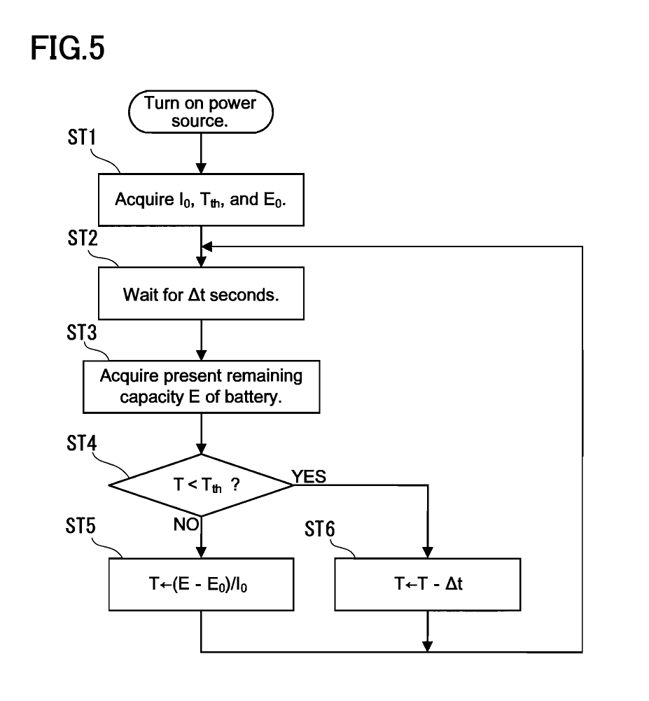

When the battery 201 is mounted on the video camera 101 and the power source of the video camera 101 is turned on, the charging microcomputer 103 judges whether the battery 201 is a usable one. Specifically, the charging microcomputer 103 exchanges information with the battery microcomputer 202 and certifies the battery 201. If the certification fails, the charging microcomputer 103 does not accept the power supply from the battery 201 and the video camera 101 does not start operating. If the certification is successful, the charging microcomputer 103 accepts the power supply from the battery 201 and the video camera 101 starts operating. After the operation starts, the charging microcomputer 103 starts the process shown in FIG. 5.

First, the charging microcomputer 103 acquires the average current consumption I₀, the threshold time Tₜₕ, and the correction value E₀ from the battery microcomputer 202 as the information regarding the battery 201 (ST1). In the present embodiment, all of these values are held in the battery microcomputer 202. However, these values may be held in the charging microcomputer 103.

Subsequently, the charging microcomputer 103 waits until the given time Δt passes using the timer 13b (ST2). The given time Δt denotes a control period for calculating the remaining usable time. If the given time Δt has passed, the charging microcomputer 103 queries the battery microcomputer 202 and acquires the present remaining capacity E of the battery 201 (ST3). The step for acquiring the remaining capacity E of the battery 201 may be executed between Step ST4 and Step ST5.

Next, remaining usable time T calculated in the previous control period is compared with the threshold time Tₜₕ (ST4). If the remaining usable time T is equal to or more than the threshold time Tₜₕ, a new remaining usable time T to be held is calculated (ST5) using formula (2) below.

T=(E−E₀)/I₀ (2)

If the remaining usable time T calculated in the previous control period is less than the threshold time Tₜₕ, the new remaining usable time T to be held is calculated by subtracting the given time Δt from the remaining usable time T calculated in the previous control period (ST6).

In the flow chart shown in FIG. 5, the remaining usable time T is calculated based on the remaining capacity E of the battery 201 detected by the battery remaining capacity detector 13a and the current consumption I of the video camera 101 (the average current consumption I₀ in the present embodiment), during the period from when the video camera 101 starts operating using the battery 201 until the remaining usable time T of the battery 201 reaches the predetermined threshold time Tₜₕ. The remaining usable time T is calculated based on the operating time measured by the timer 13b, during the period from after the remaining usable time

T becomes less than the predetermined threshold time Tₜₕ until the remaining usable time T becomes zero. Specifically, the new remaining usable time T to be displayed on the liquid crystal monitor 102 is calculated by subtracting successively the control period Δt (the operating time) measured by the timer 13b from the remaining usable time T.

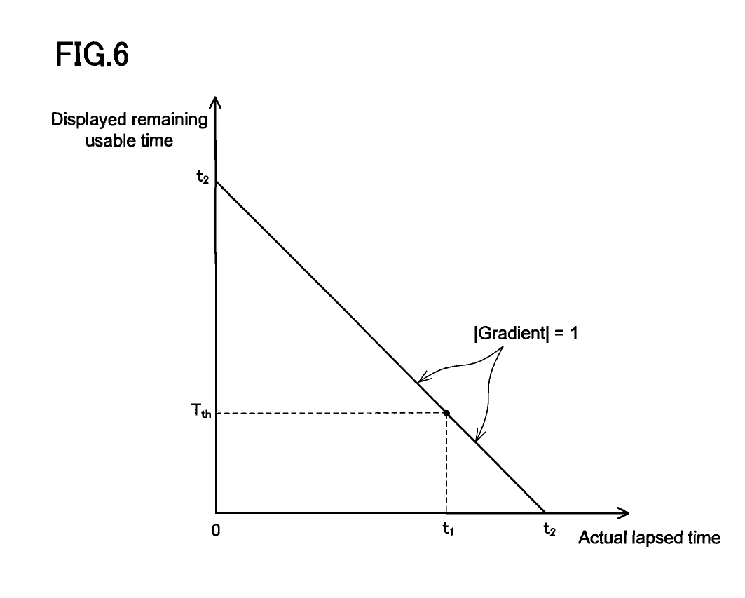

The remaining usable time thus calculated is displayed on the liquid crystal monitor 102. As shown in FIG. 6, the remaining usable time displayed on the liquid crystal monitor 102 continues decreasing to zero at approximately the same rate as that of the actual lapsed time. In the present embodiment, it is possible to keep the battery from being exhausted before the displayed remaining usable time reads zero, and avoid the displayed remaining usable time reading zero in a state where the remaining capacity of the battery is still sufficient. Moreover, the present embodiment makes it possible to prevent a phenomenon in which the displayed remaining usable time fails to decrease, and a phenomenon in which the displayed remaining usable time decreases suddenly and significantly. A user can know accurately the time to replace the battery 201 and the time to charge the battery 201, etc. by referring to the remaining usable time displayed on the liquid crystal monitor 102.

(4. Modified Examples)

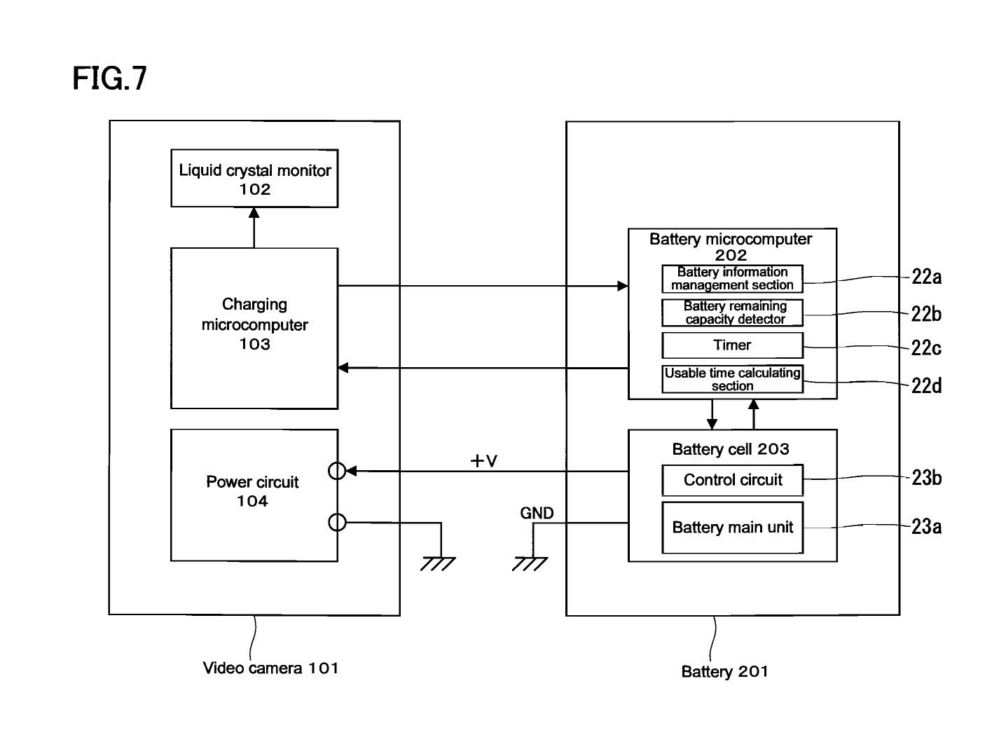

In the embodiment described with reference to FIG. 1, etc., the charging microcomputer 103 of the video camera 101 calculates the remaining usable time. However, the battery microcomputer 202 may execute the operation for calculating the remaining usable time. More specifically, the battery microcomputer 202 may include the battery remaining capacity detector 22b, the timer 22c, and the usable time calculating section 22d as shown in FIG. 7. The charging microcomputer 103 queries the battery microcomputer 202 about the calculation result of the remaining usable time, and allows the liquid crystal monitor 103 to display the remaining usable time acquired from the battery microcomputer 202. In the modified example shown in FIG. 7, the electronic device of the present invention can be composed of the video camera 101 and the battery 201 mounted on the video camera 101.

Furthermore, in the operation for calculating the remaining usable time, a value regarding the remaining capacity of the battery can be used instead of the remaining capacity of the battery. For example, a value found by rounding off the remaining capacity of the battery can be used as the value regarding the remaining capacity of the battery. Likewise, a value regarding the current consumption can be used instead of the current consumption. As the value regarding the current consumption, a value found by rounding off the current consumption, a predetermined value of the average current consumption of the electronic device, a value of an actual current, etc. can be used.

In the embodiment, the remaining usable time is calculated with the timer 13b from the point of time when the remaining usable time calculated by (E−E₀)/I₀ becomes less than the threshold time Tₜₕ. Instead of this, the remaining usable time may be calculated using the timer 13b from a point of time when the following conditions (i) to (v) are satisfied, for example. These modified examples technically are equivalent to the embodiment in which whether the remaining usable time calculated by (E−E₀)/I₀ becomes less than the threshold time Tₜₕ is judged.

(i) The remaining capacity E of the battery 201 is less than a predetermined value.

(ii) The current consumption I exceeds a predetermined value.

(iii) An amount of variation ΔI in the current consumption I during the given time Δt exceeds a predetermined value.

(iv) The voltage of the battery 201 is less than a predetermined value.

(v) Absolute value |ΔV| of an amount of variation in the voltage V of the battery 201 during the given time Δt exceeds a predetermined value.

The present invention advantageously can be applied to various electronic devices driven by a battery, such as a video camera, a still camera, mobile communications equipment, a portable media player, a portable game machine, an electronic notebook, and a notebook computer. The present invention particularly is effective for electronic devices, such as a video camera, that are expected to provide significantly enhanced convenience by informing accurately the times to replace and charge the battery.

The present invention may be embodied in other forms without departing from the spirit or essential characteristics thereof. The embodiments disclosed in this specification are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. An electronic device comprising:
a battery remaining capacity detector configured to detect a remaining capacity of a battery;
a timer configured to measure an operating time of the electronic device;
a usable time calculating section configured to: (i) calculate a remaining usable time based on a value regarding the remaining capacity of the battery detected by the battery remaining capacity detector and a value regarding a current consumption of the electronic device, during a period from when the electronic device starts operating using the battery until the remaining usable time of the battery reaches a predetermined threshold time, and (ii) calculate the remaining usable time based on the operating time measured by the timer, during a period from after the remaining usable time becomes less than the threshold time until the remaining usable time becomes zero; and
a display unit configured to display information regarding the remaining usable time calculated by the usable time calculating section.

2. The electronic device according to claim 1, wherein the value regarding the current consumption is a predetermined value of an average current consumption of the electronic device.

3. The electronic device according to claim 1, wherein in the process (i), a time less than the remaining usable time that can be calculated by dividing the value regarding the remaining capacity of the battery with the value regarding the current consumption is calculated as the remaining usable time to be displayed on the display unit.

4. The electronic device according to claim 1, wherein in the process (i), the remaining usable time to be displayed on the display unit is calculated by dividing a value found by subtracting a predetermined correction value from the value regarding the remaining capacity of the battery by the value regarding the current consumption.

5. The electronic device according to claim 4, wherein:
the value regarding the current consumption is a predetermined value of an average current consumption of the electronic device; and
when the value regarding the remaining capacity of the battery at a point of time when the remaining usable time reaches the threshold time is defined as E(t₁), the correction value is represented by the following formula.
E(t₁)=(the correction value)+(the value of the average current consumption)×(the threshold time)

6. The electronic device according to claim 1, wherein in the process (ii), a new remaining usable time to be displayed on the display unit is calculated by subtracting successively the operating time measured by the timer from the remaining usable time.

7. The electronic device according to claim 1, wherein the battery is composed of a lithium ion secondary battery.

8. A method for calculating a remaining usable time of a battery, comprising the steps of
detecting a remaining capacity of the battery;
measuring an operating time of an electronic device connected to the battery;
calculating the remaining usable time based on a value regarding the detected remaining capacity of the battery and a value regarding a current consumption of the electronic device, during a period from when the electronic device starts operating using power of the battery until the remaining usable time of the battery reaches a predetermined threshold time;
calculating the remaining usable time based on the operating time measured by the timer, during a period from after the remaining usable time becomes less than the threshold time until the remaining usable time becomes zero; and
displaying information regarding the calculated remaining usable time.
